(19) United States
(12) Patent Application Publication
(10) Pub. No.: US 2010/0111126 A1
(43) Pub. Date: May 6, 2010

(54) SEMICONDUCTOR LASERS

(76) Inventors: Junichiro Shimizu, Hadano (JP); Etsuko Nomoto, Sagamihara (JP); Shinichi Nakatsuka, Hino (JP); Tsukuru Ohtoshi, Hanno (JP); Takafumi Taniguchi, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/608,346

(22) Filed: Oct. 29, 2009

(30) Foreign Application Priority Data
Oct. 30, 2008 (JP) 2008-279475

(51) Int. Cl. H01S 5/00

(52) U.S. Cl. 372/45.01

(57) ABSTRACT

In a horizontal-cavity vertical-emitting semiconductor laser including an Al-containing semiconductor layer, deterioration of light output property due to oxidization of the Al-containing semiconductor layer is suppressed. A lower cladding layer, an active layer, and an upper cladding layer are stacked in this order from the lower layer on a main surface of a substrate made of GaAs. The upper cladding layer is made of AlGaAs or AlGaInP containing Al in high concentration. An emitting plane layer combining a function of preventing the oxidization of Al contained in the upper cladding layer is formed on an upper portion of the upper cladding layer, and an electric contact layer is formed on an upper portion of the emitting plane layer. The emitting plane layer is made of InGaP, and the electric contact layer is made of GaAs.

### CROSS-REFERENCE TO RELATED APPLICATION

The present application claims priority from Japanese Patent Application No. JP 2008-279475 filed on Oct. 30, 2008, the content of which is hereby incorporated by reference into this application.

### TECHNICAL FIELD OF THE INVENTION

The present invention relates to a semiconductor laser used for optical information recording, high-speed optical communication, laser beam machining, laser printer, or the like. More particularly, the present invention relates to a technique effectively applied to a horizontal-cavity vertical-emitting semiconductor laser.

### BACKGROUND OF THE INVENTION

In these years, digitalization and high quality of information such as voice or image, etc. have been advanced with development of the information society, and data traffic of the Internet has significantly increased. As a result, electronic data volume stored in a server or the like has increased, and therefore, it is required to achieve high speed and large volume for information record system and/or internet communication network.

With respect to such a requirement, a role played by high functionalization of optical parts is large, and more particularly, a semiconductor laser (hereinafter, simply called laser), which is a light source device, being central to the optical parts has been significantly developed in points of high speed and high power.

Generally, a laser includes an active layer generating light therein and an optical waveguide. Normally, the active layer is inside the optical waveguide, and a cavity required for laser oscillation is formed so as to sandwich both ends of the optical waveguide by reflective mirrors. The reflective mirror for providing the cavity is normally manufactured by making its plane by cleavage or etching.

A laser of this type is roughly categorized into a horizontal-cavity type and a vertical-cavity type by a direction of a cavity with respect to a stacked layer direction of semiconductor layers (crystal), and the one in which the cavity is formed in a parallel direction to the stacked layer plane of the semiconductor layers is called a horizontal-cavity laser, and the one in which the cavity is formed in a penetrating direction to the stacked layer plane of the semiconductor layers is called a vertical-cavity laser.

Also, the laser of this type is categorized into a horizontal-emitting type (edge-emitting type) and a vertical-emitting type (surface-emitting type) by a position of an optical emitting plane with respect to the stacked layer direction of the semiconductor layers. From the laser, light not reflected but transmitted among the light reaching the reflective mirrors provided on both ends of the cavity is extracted as laser light, and therefore, normally, a horizontal-cavity laser is the horizontal-emitting type, and a vertical-cavity laser is the vertical-emitting type.

A laser of the horizontal-cavity type and the horizontal-emitting type has a cavity which is relatively long and in parallel with the stacked layer plane of the semiconductor layers, that is a main surface of a semiconductor substrate (hereinafter, simply called substrate), and therefore, it has such characteristics that a volume of the active layer generating gains can be largely provided, so that high power can be easily obtained. On the other hand, it is difficult to integrate many chips because the facet is formed by cleavage.

Meanwhile, in a laser of the vertical-cavity type and the vertical-emitting type, the optical waveguide is formed vertically to the main surface of the substrate, and therefore, the laser light is emitted from an upper plane (front plane) of the substrate or a lower plane (rear plane) of the same. Accordingly, since it is not required to form the cavity by the cleavage, there are such characteristics that many chips can be easily integrated or easily mounted. On the other hand, sufficient gain cannot be obtained because the cavity is short, and therefore, it is difficult to obtain high power.

Further, in addition to the two types of lasers described above (the horizontal-cavity horizontal-emitting laser and the vertical-cavity vertical-emitting laser), there is a laser of the horizontal-cavity type and the vertical-emitting type. This is a structure in which the laser light proceeding in a longitudinal direction of the cavity in parallel with the main surface of the substrate is guided toward a direction vertical to the main surface of the substrate and is emitted. The structure has an advantage combining the high power property of the horizontal-cavity type and the high integration property of the vertical-emitting type. However, it is required to rotate the proceeding direction of the laser light by an angle of 90 degrees, and therefore, its manufacture is difficult as compared with the two types of lasers described above, and it has not been in the mainstream of the laser market yet.

The horizontal-cavity vertical-emitting laser has two types mainly categorized by a difference in the optical emitting plane. One of them is such that the upper plane (front surface) of the substrate is the optical emitting plane, and the other is such that the lower plane (rear surface) of the substrate is the optical emitting plane. Hereinafter, the one emitting the light from the upper plane side of the substrate is called an upper-surface emitting type, and the one emitting the light from the lower plane side of the substrate is called a lower-surface emitting type.

The horizontal-cavity vertical-emitting laser is described in, for example, Japanese Patent Application Laid-Open Publication No. H11-289132 (Patent Document 1), Japanese Patent Application Laid-Open Publication No. H02-094685 (Patent Document 2), and so forth.

As means of rotating the laser light proceeding in the direction parallel to the main surface of the substrate to the vertical direction, many horizontal-cavity vertical-emitting lasers use a reflective mirror on an end portion of the cavity as disclosed in, for example, Patent Document 1. When a reflective mirror having an angle of, for example, 45 degrees with respect to the cavity is provided on one end of the cavity, the laser light in the optical waveguide arranged in a horizontal direction inside the laser is reflected at the reflective mirror, and is rotated by 90 degrees with respect to the longitudinal direction of the cavity to head toward the upper plane direction or lower plane direction of the substrate.

While the reflective mirror is monolithically integrated on the substrate often and is sometimes integrated outside the cavity, sometimes a cavity is formed being provided inside the Fabry-Perot cavity and whose end portion is bent. When the inclined reflective mirror is formed at the end portion of the cavity, a technique of etching process for the stacked layer structure of the semiconductor layers is used.

In the horizontal-cavity vertical-emitting laser, the laser light reflected on the inclined reflective mirror at the end portion of the cavity passes a plurality of semiconductor layers stacked on the substrate so as to penetrate the semiconductor layers. However, while these semiconductor layers are required to be transparent with respect to a wavelength of the laser light for the laser light to pass, the semiconductor layers may not be transparent because of a relation of a band gap of a used semiconductor material and an oscillating wavelength of the laser light.

For example, in a laser using GaAs as the substrate, light having a wavelength of about 600 to 1100 nm is obtained. While the GaAs substrate is transparent with respect to light of about 870 nm or longer wavelength that is longer than its band gap, it is non-transparent with respect to light of about 870 nm or shorter. Therefore, by the laser using the GaAs substrate and having the wavelength of about 870 nm or shorter wavelength, the horizontal-cavity vertical-emitting laser of the lower-surface emitting type cannot be manufactured. That is, the horizontal-cavity vertical-emitting laser having the short wavelength is the upper-surface emitting type.

Also, the laser having a short wavelength of 850 nm or shorter normally includes an active layer and a cladding layer in which the band gap is adjusted with using a material containing high-concentration Al. An Al-containing semiconductor layer having a high Al concentration is easily oxidized when it is exposed to air, and Al oxides harm light output property and lifetime of the laser.

That is, when Al oxides are generated in the high-concentration Al-containing semiconductor layer, impurity states caused by the impurity or crystal defects and absorbing the laser light during the light emission is generated, and the temperature of a portion absorbing the laser light is raised by the absorption. And, the band gap is narrowed by the rising temperature to accelerate light absorption in its peripheral portion, and further light absorption is caused. As a result, the temperature is further raised, and the portion is destroyed. The phenomenon is generally known as catastrophic optical damage (COD).

It is assumed that the above description is applied to not only the facet formed by cleavage but also the plane to be the optical emitting plane and the inclined reflective mirror. Therefore, for preventing the COD, it is normally effective not to expose the Al-containing portion or to coat the exposed portion by a thin film even when the Al-containing portion is exposed. For example, Japanese Patent Application Laid-Open Publication No. 2001-156383 (Patent Document 3) and Japanese Patent Application Laid-Open Publication No. 2005-175111 (Patent Document 4) disclose techniques of coating the exposed portion by an Al₂O₃-based thin film for preventing the COD due to the exposure of the Al-containing portion.

### SUMMARY OF THE INVENTION

The above-described Patent Document 1 discloses a horizontal-cavity vertical-emitting laser of an upper-surface emitting type. Generally, in the horizontal-cavity vertical-emitting laser of the upper-surface emitting type as described in Patent Document 1, Al contents of the active layer and the cladding layer cannot be reduced in order to maintain a confinement function of carrier or light, and therefore, there is an issue that the prevention of Al oxidization cannot be avoided.

An embodiment of the above-described Patent Document 1 discloses that an etching stopper layer is provided between a cladding layer and a contact layer, and also discloses that AlAs having a high Al concentration is used for the etching stopper layer. Also, the Patent Document 1 discloses that the Al content of the cladding layer is reduced by providing a carrier blocking layer with considering deterioration due to the oxidation of the cladding layer exposed to the inclined reflective mirror. However, the band gap of the semiconductor material becomes small because of the reduction of the Al content, and therefore, it is difficult to satisfy the transparent condition with respect to the oscillated light. Also, a refractive index of the cladding layer is increased and the light confinement amount of the active layer is changed, and therefore, the reduction of Al content negatively affects the light output property. Accordingly, the Al composition is an important parameter affecting the laser's own properties, and therefore, the composition change without careful consideration is difficult.

Further, the horizontal-cavity vertical-emitting laser disclosed in the above-described Patent Document 2 is an element guiding the laser light with using its inclined plane as the reflective mirror and is a lower-surface emitting type. On a plurality of semiconductor layers including a GaAs substrate, there is formed an inclined plane to be a reflective mirror having an obtuse angle with respect to the stacked layer plane, and an electrode is arranged so as to avoid the emitting window. Since the GaAs substrate is used for the emitting plane in the laser, Al is not exposed at the emitting plane. However, such a structure emitting the light from the substrate side is limited to a laser having a relatively long wavelength band in which GaAs is transparent.

A preferred aim of the present invention is to provide a technique capable of surely suppressing deterioration of a light output property due to oxidization of an Al-containing semiconductor layer in a horizontal-cavity vertical-emitting semiconductor laser having a cavity including the Al-containing semiconductor layer.

The above and other preferred aims and novel characteristics of the present invention will be apparent from the description of the present specification and the accompanying drawings.

As a countermeasure of preventing the oxidization of the Al content semiconductor layer configuring the cavity in the horizontal-cavity vertical-emitting laser having an upper-surface-emitting type structure, the Al-containing semiconductor layer has been multilayered and an Al content of an Al-containing semiconductor layer close to the emitting plane has been reduced by the present inventors. More specifically, in the horizontal-cavity vertical-emitting laser having the upper-surface-emitting type structure, when at least an upper cladding layer of an active layer and upper and lower cladding layers sandwiching the active layer has been formed of the Al-containing semiconductor layer, the upper cladding layer has been multilayered to have an optical function and an antioxidant function, which are main functions of the cladding layer, in different layers to each other. That is, a high-Al-content upper cladding layer for controlling the confinement of the laser light has been arranged on the active layer side, and a low-Al-content layer having the Al antioxidant function has been arranged on the emitting plane side.

In this case, when a thickness of the high-Al-content cladding layer is insufficient, an optical field is affected and the optical function cannot sufficiently work. Therefore, it is preferable to form the high-Al-content cladding layer with a sufficient thickness as thick as a conventional cladding layer and to form the low-Al-content cladding layer having the antioxidant function so as to sufficiently be away from the active layer. Note that the whole cladding layer becomes thick when the low-Al-content cladding layer becomes thick, and therefore, the thickness may be sufficiently thin to the extent that there is no difficulty for its manufacture.

Also, from a point of view of suppressing the oxidization of the high-Al-content cladding layer, a lower Al concentration of the low-Al-content cladding layer is more preferable, and ultimately, an Al-free layer not containing Al at all is preferable. In other words, it is preferable that an antioxidant layer formed of the low-Al-content semiconductor layer or the Al-free semiconductor layer is arranged between the upper cladding layer and a semiconductor layer (electric contact layer) above the upper cladding layer. Note that the low-Al-content semiconductor layer or the Al-free semiconductor layer is required to pass the laser light, and therefore, it must be transparent with respect to an oscillated wavelength of the laser light.

Further, since the low-Al-content cladding layer is sandwiched by the electric contact layer and the high-Al-content cladding layer, it is required to connect the low-Al-content cladding layer to these both layers so as not to cause a barrier in the energy band. That is, it is required to form the low-Al-content cladding layer by a semiconductor material having a band gap positioned between a band gap of the electric contact layer and a band gap of the upper cladding layer or a semiconductor material relaxing the energy barrier for carriers between the electric contact layer and the upper cladding layer. Otherwise, resistance is caused to increase voltage when current is injected into the laser, and therefore, the laser's properties are deteriorated.

For example, in a laser in which the upper cladding layer is made of AlGaAs or AlGaInP and the electric contact layer is made of GaAs, it is desired to form the low-Al-content cladding layer by InGaP. This is because InGaP is an Al-free material and has a band gap between those of the upper cladding layer (AlGaAs or AlGaInP) and the electric contact layer (GaAs), and therefore, InGaP is continuously connected in the energy band. Also, if the InGaP layer itself can be used as the cladding layer depending on the wavelength band of the laser light, it is not required to separately consider the cladding layer and the antioxidant layer, and therefore, it is convenient.

Further, since the low-Al-content cladding layer having the Al antioxidant function is the emitting plate in the laser of the present invention, a part of the electric contact layer is removed by etching to expose the low-Al-content cladding layer to a surface upon the manufacture. Therefore, it is required to select such a material that functions as the etching stopper layer to the electric contact layer for the low-Al-content cladding layer.

Still further, a reflectance controlling film similar to that of the edge-emitting type laser is formed on a surface of the low-Al-content cladding layer for improving the emission property. In this manner, the oxidization due to the exposure of the low-Al-content cladding layer can be prevented by protecting the surface of the low-Al-content cladding layer with the reflectivity (reflectance) controlling film, and therefore, the emission property and the reliability can be further improved.

Moreover, in the laser of the present invention, it is required to form the inclined plane to be the reflective mirror so as to have an angle of precisely 45 degrees with respect to an upper surface of the substrate. Since the upper surface of the substrate is a front facet of the cavity, the upper surface is the reflective mirror and also the optical emitting plane. If the reflective mirror angle is shifted, a direction of the laser light reflected on the reflective mirror is shifted from the vertical direction, and therefore, a direction of incident laser light on the substrate upper surface being the front facet of the cavity is not at 90 degrees with respect to the upper surface. This is not preferable for the properties because directions of transparent laser light and the incident laser light are shifted from the vertical direction. Also, the reflective mirror is required to be flat and smooth not to cause diffuse reflection or scattering of the laser light. Otherwise, re-absorption of the laser light is caused to result in the COD, and therefore, the flatness and smoothness of the reflective mirror become the important parameters.

According to the consideration of the above points, from a point of view of the flatness and smoothness and the angle controllability, it is desired to use a dry etching method when the reflective mirror is formed by an etching method. This is because an etching rate in each semiconductor layer is different in a wet etching method, and therefore, the reflective mirror surface becomes non-flat. And, the plane of the semiconductor layer (crystal) grown on the GaAs substrate normally is (100) oriented plane. Therefore, the plane inclined at an angle of 45 degrees is not a crystallographical plane, and therefore, it is difficult to manufacture the reflective mirror by the method of forming the crystal plane with using the wet etching method.

Also, it is required to precisely control an etching direction for forming the inclined reflective mirror, and therefore, a reactive ion beam etching method of dry etching methods is suitable. However, a plasmized gas is normally used in a dry etching process, and therefore, impurity ions are implanted to the etched surface to form a thin damaged layer. Accordingly, it is concerned that the damaged layer forms an impurity state to cause the COD. Therefore, after forming the reflective mirror by dry etching, a process of removing the damaged layer by weak wet etching may be added.

Further, since the Al-containing layer is exposed on the inclined reflective mirror, it is desired to protect the reflective mirror after removing the damaged layer. In the present invention, the reflective mirror is covered by a protective film to prevent the oxidization of the Al-containing layer. The protective film is required not to affect the reflection of the laser light on the reflective mirror and not to cause the absorption of the laser light. Therefore, an insulating dielectric film having a low refractive index and being transparent with respect to the laser light is desired. Also, it is required to coat the reflective mirror on the inclined plane having an acute angle, and therefore, a chemical vapor deposition (CVD) method having good coverage property and being able to thickly form the film is the most suitable as the thin-film deposition method.

While there are various materials for the protective film, insulating films generally most-used for the laser are made of SiO₂ and SiNₓ. They can be easily formed by a plasma CVD method, a thermal CVD method, or the like, and can be thickly deposited even on the inclined plane having an acute angle. And, since these materials are also used as a passivation film for the laser, the protective film for the reflective mirror and the passivation film can be simultaneously formed by selecting these materials.

As described above, Patent Documents 3 and 4 describe that it is effective to deposit an Al₂O₃-based thin film for preventing the COD due to the exposure of the Al-containing portion. In the cases of the lasers described in these documents, the Al₂O₃-based thin film on a facet is also combined with a film for controlling the reflectance, and therefore, strict film thickness control is required. Although a sputtering method is normally suitable for the film thickness control, its film growth rate is slow and its wraparound is also small in the sputtering method in general, and therefore, it is not easy to deposit the film having a certain degree of thickness on the inclined plane inclined at an acute angle.

On the other hand, the inclined reflective mirror in the laser of the present invention is a plane totally reflecting the laser light, and therefore, the strict film thickness control is not required. Therefore, by depositing the Al₂O₃-based protective film with using the CVD method on the reflective mirror inclined at the acute angle of 45 degrees, the COD can be prevented. For example, when the film is deposited by the thermal CVD method, a film having a thickness of several hundred nanometers can be deposited in a short time of several ten minutes even on the inclined plane, and therefore, the Al content inclined reflective mirror is covered by an Al₂O₃ film having a sufficient thickness, so that the reliability of the laser can be improved.

Also, by forming the protective film on the inclined reflective mirror so as to connect to the reflectivity controlling film on the antioxidant layer combining with the emitting plate layer, the Al-containing layer is not exposed, so that a highly reliable laser can be achieved.

Further, for suppressing the re-absorption of the laser light, it is considered effective in the reliability to form so-called window structure in which metal impurities are diffused so as to be adjacent to the light-reflecting plane or the like. Since the window structure suppresses the re-absorption of the laser light, it suppresses not only the COD but also the saturable absorption, and therefore, it is convenient also in emission properties.

Still further, in the reflectivity controlling films on the substrate upper surface and on the other facet of the cavity, by setting a laser light reflectance of the reflectivity controlling film on the substrate upper surface to be relatively low, that is, setting a transmittance to be relatively high and setting a laser light reflectance of the reflectivity controlling film on the other facet to be relatively high, the light output from the substrate upper surface can be made large. This is the same principle as changing a ratio of the light outputs on front and rear facets to take more laser light out from the front facet by setting the reflectance of the front facet in a normal edge-emitting laser to be relatively low and setting the reflectance of the rear facet to be relatively high.

Still further, on the other hand, when the laser light reflectance of the facet is set to be relatively low and the laser light reflectance of the substrate upper surface is set to be relatively high, more laser light is emitted from the facet. While such a laser is one type of the edge-emitting laser, it has an advantage which cannot be obtained in a normal edge-emitting laser.

That is, a front facet and a rear facet of a normal horizontal-emitting (edge-emitting) laser are formed by cleavage. In the horizontal-emitting laser, a distance between the front facet and the rear facet is a length of its cavity. While a thickness of a normal semiconductor laser is about 100 to 150 μm, the length of the cavity which can be formed by the cleavage is 150 μm at the longest as same as the thickness of the laser when an aspect ratio in the cleavage process for cleaving (splitting) is taken into consideration even if using a sophisticated cleavage system. If the cavity is bent on the inclined reflective mirror having the angle of 45 degrees to make one facet be the upper surface, a facet to be formed by the cleavage is one and is thus determined by only accuracy of forming the one cleavage plane, and therefore, a short cavity of 150 μm or shorter is easily manufactured.

Problems of a horizontal-cavity horizontal-emitting laser manufactured in this manner are the same as those of the horizontal-cavity vertical-emitting laser, and the deterioration due to the oxidization of the Al-containing semiconductor layer is surely suppressed by employing the configuration of the present invention described above, so that the horizontal-cavity horizontal-emitting laser having high reliability can be fabricated.

The typical ones of the inventions disclosed in the present application will be briefly described as follows.

In the horizontal-cavity vertical-emitting semiconductor laser having the cavity including the Al-containing semiconductor layer, the oxidization of the Al-containing semiconductor layer is suppressed, and therefore, the deterioration of the light output property caused by the oxidization can be surely suppressed.

### BRIEF DESCRIPTIONS OF THE DRAWINGS

FIG. 1 is a perspective view illustrating a horizontal-cavity vertical-emitting laser according to a first embodiment of the present invention;

FIG. 2 is a cross-sectional view illustrating the horizontal-cavity vertical-emitting laser according to the first embodiment;

FIG. 3 is a perspective view illustrating a horizontal-cavity horizontal-emitting laser according to a second embodiment of the present invention;

FIG. 4 is a cross-sectional view illustrating the horizontal-cavity horizontal-emitting laser according to the second embodiment;

FIG. 5 is a cross-sectional view illustrating a horizontal-cavity vertical-emitting laser according to a third embodiment of the present invention; and

FIG. 6 is a cross-sectional view illustrating a horizontal-cavity vertical-emitting laser according to a fourth embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted. In addition, the description of the same or similar portions is not repeated in principle unless particularly required in the following embodiments. Also, in some drawings describing the following embodiments, hatching is used even in a plan view so as to make the configurations easy to understand.

### First Embodiment

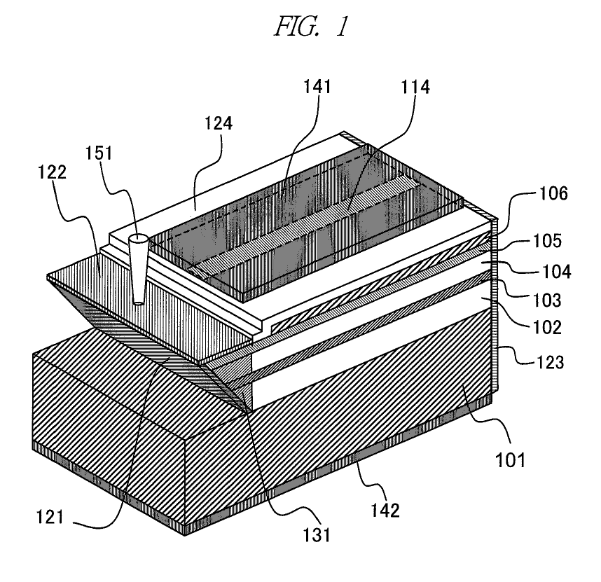

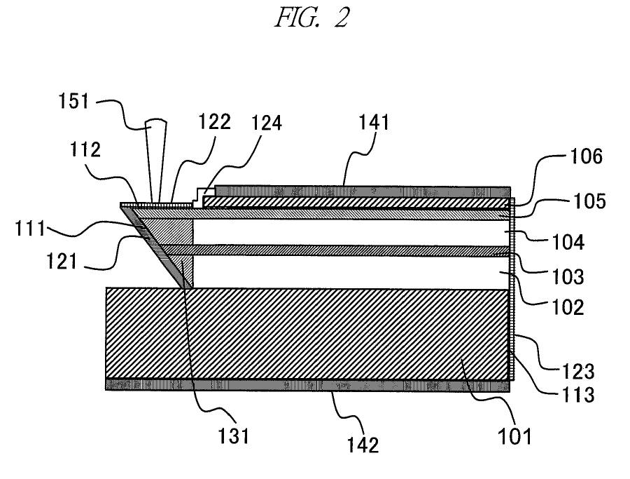

FIG. 1 is a perspective view illustrating a horizontal-cavity vertical-emitting laser according to the embodiment, and FIG. 2 is a cross-sectional view along a longitudinal direction of a cavity of the horizontal-cavity vertical-emitting laser illustrated in FIG. 1.

On a main surface of a substrate 101 made of GaAs, there are stacked a lower cladding layer 102, an active layer 103, and an upper cladding layer 104 in this order from a lower layer. The lower cladding layer 102, the active layer 103, and the upper cladding layer 104 are formed of an Al-containing semiconductor layer, and the upper cladding layer 104 is made of AlGaAs or AlGaInP containing Al in a high concentration.

On an upper portion of the upper cladding layer 104, there is formed an emitting plate layer 105 combining a function of preventing the oxidization of Al contained in the upper cladding layer 104, and, on an upper portion of the emitting plate layer 105, there is formed an electric contact layer 106. The emitting plate layer 105 is made of InGaP which is an Al-free material, and the electric contact layer 106 is made of GaAs.

On an upper portion of the electric contact layer 106, there is formed a passivation film 124 made of SiO₂ or SiNₓ, and, on an upper portion of the passivation film 124, there is formed an electrode 141. Also, in a part of the passivation film 124, there is provided a via hole 114, and the electrode 141 is electrically connected to the electric contact layer 106 of the lower layer through the via hole 114. Meanwhile, on a lower surface of the substrate 101, there is formed an electrode 142 which is paired with the electrode 141.

In a region to be an emitting plane 112 of the emitting plate layer 105, the electrode 141 and the passivation film 124 on the region are removed, and the emitting plate layer 105 configures the most upper surface layer of the semiconductor layers. And, on an upper portion of the emitting plate layer 105 in this region, there is formed a reflectivity controlling film 122 through which an emitted light 151 transmits.

On the lower cladding layer 102, the active layer 103, and the upper cladding layer 104 below the emitting plane 112, there is formed an inclined reflective mirror 111 inclined at an acute angle of 45 degrees with respect to an upper surface of the substrate 101, and a surface of the inclined reflective mirror 111 is covered by a protective film on inclined reflective mirror 121. Also, in the lower cladding layer 102, the active layer 103, and the upper cladding layer 104 in the vicinity of the inclined reflective mirror 111, there is formed an impurity diffusion region 131 to be the window structure.

Meanwhile, on a facet 113 positioned on an opposite side of the inclined reflective mirror 111, there is formed a reflectivity controlling film 123. A laser light reflectance of the reflectivity controlling film 123 is higher than that of the reflectivity controlling film 122 configuring the most upper plane of the emitting plane 112, and such a configuration is made that most of the laser light is emitted from the emitting plane 112.

### Second Embodiment

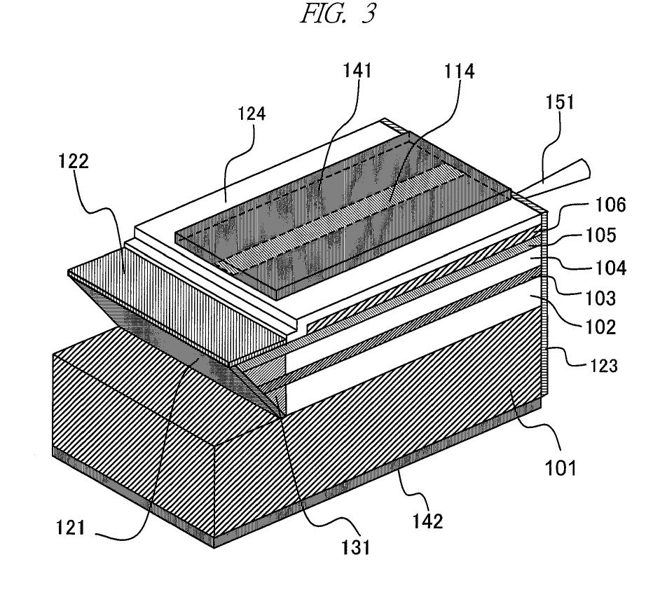

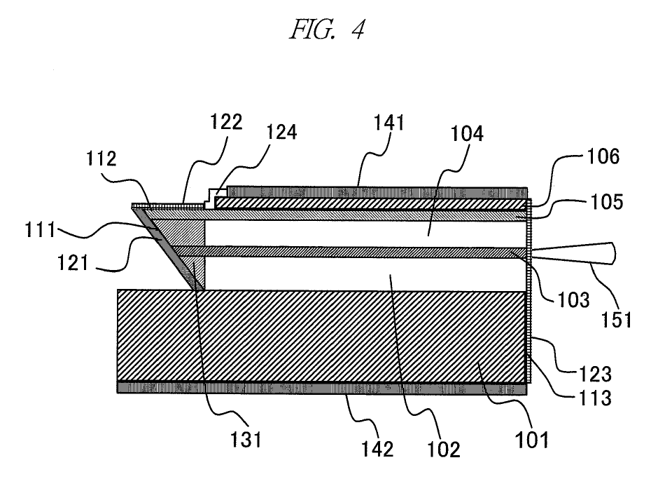

FIG. 3 is a perspective view illustrating a horizontal-cavity horizontal-emitting laser having a short cavity type structure according to the present embodiment, and FIG. 4 is a cross-sectional view along a longitudinal direction of a cavity of the horizontal-cavity horizontal-emitting laser illustrated in FIG. 3.

In the laser according to the first embodiment, the laser light reflectance of the reflectivity controlling film 123 is higher than that on the reflectivity controlling film 122. On the other hand, in the laser according to the present embodiment, such a configuration is made that most of the laser light is emitted from an facet where the reflectivity controlling film 123 is formed, by setting a laser light reflectance of the reflectivity controlling film 122 to be relatively higher than that of the reflectivity controlling film 123. Other configurations are the same as those of the laser according to the first embodiment, and therefore, descriptions thereof are omitted.

### Third Embodiment

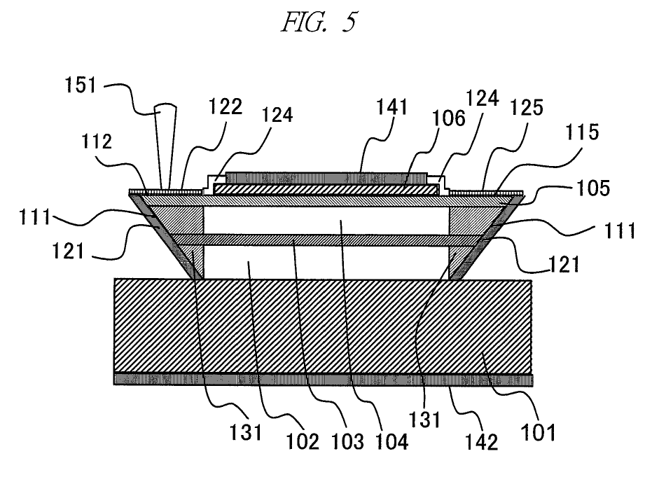

FIG. 5 is a cross-sectional view along a longitudinal direction of a cavity of a horizontal-cavity vertical-emitting laser according to the present embodiment.

While the inclined reflective mirror 111 is formed on one end in the longitudinal direction of the cavity in the laser according to the first embodiment, the inclined reflective mirrors 111 and 111 are formed on both ends in the longitudinal direction of the cavity in the laser according to the present embodiment. And, a surface of each inclined reflective mirror 111 is covered by the protective film on inclined reflective mirror 121.

In a region to be the emitting plane 112, the electrode 141 and the passivation film 124 above the emitting plane layer 105 are removed, and the emitting plane layer 105 configures the most upper surface layer of the semiconductor layers. And, on an upper portion of the emitting plate layer 105 in this region, there is formed the reflectivity controlling film 122 through which the emitted light 151 transmits.

On the other hand, in a region to be a light-reflecting plane 115, the electrode 141 and the passivation film 124 on the emitting plane layer 105 are removed, and the emitting plane layer 105 configures the most upper surface layer of the semiconductor layers. And, on an upper portion of the emitting plane layer 105 in this region, there is formed the reflectivity controlling film 125 having a higher laser light reflectance than that of the reflectivity controlling film 122.

Other configurations are the same as those of the laser according to the first embodiment, and therefore, descriptions thereof are omitted.

According to the above-described configuration, quantity of the laser light emitted from the emitting plane 112 is larger than that from the light-reflecting plane 115. Accordingly, by setting a laser light reflectance of the reflectivity controlling film 125 to be 100% or a value close to that, a horizontal-cavity vertical-emitting laser emitting the laser light from the emitting plane 112 can be fabricated.

### Fourth Embodiment

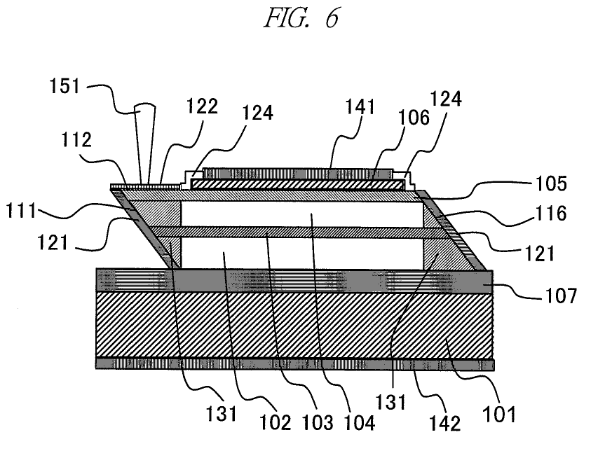

FIG. 6 is a cross-sectional view along a longitudinal direction of a cavity of a horizontal-cavity vertical-emitting laser according to the present embodiment.

In the laser according to the present embodiment, the inclined reflective mirrors 111 and 116 are formed respectively on two ends in the longitudinal direction of the cavity. And, a surface of each of the inclined reflective mirrors 111 and 116 is covered by the protective film on inclined reflective mirror 121.

The inclined reflective mirror 111 on the emitting plane 112 side of the above-described two inclined reflective mirrors 111 and 116 is inclined at an acute angle of 45 degrees with respect to the upper surface of the substrate 101 similar to the embodiments 1 to 3. On the other hand, the other inclined reflective mirror 116 is inclined at an obtuse angle of 45 degrees with respect to the upper surface of the substrate 101. And, a reflective mirror 107 having a high reflectance is provided between the lower cladding layer 102 and the substrate 101. The reflective mirror 107 is formed of, for example, a distributed Bragg reflector (DBR) mirror configured with a multi-periodic structure of a high-refractive-index semiconductor layer and a low-refractive-index semiconductor layer.

Other configurations are the same as those of the laser according to the first embodiment, and therefore, descriptions thereof are omitted.

According to the above-described configuration, the laser light generated in the active layer 103 and heading toward the inclined reflective mirror 116 side is reflected on a surface of a distributed Bragg reflector mirror 107, and therefore, a horizontal-cavity vertical-emitting laser emitting the laser light only from the emitting plane 112 can be fabricated.

In the foregoing, the invention made by the inventors of the present invention has been concretely described based on the embodiments. However, it is needless to say that the present invention is not limited to the foregoing embodiments and various modifications and alterations can be made within the scope of the present invention.

Although there is formed the Al-free emitting plane layer combining the function of preventing the Al oxidization on the upper portion of the upper cladding layer in the above-described embodiment, the upper cladding layer may be multilayered and Al content may be gradually lowered from the upper cladding layer close to the active layer to the upper cladding layer close to the emitting plate layer.

The present invention can be employed for a semiconductor laser used for optical information record, high-speed optical communication, laser beam machining, laser printer, or the like.

What is claimed is:

1. A semiconductor laser of a horizontal-cavity vertical-emitting type
having a cavity including a lower cladding layer, an active layer, and an upper cladding layer stacked on a main surface of a semiconductor substrate, the cavity being formed along a direction parallel to the main surface,
having at least the upper cladding layer formed of an Al-containing semiconductor layer among the lower cladding layer, the active layer, and the upper cladding layer,
having a first reflective mirror having an inclination of an acute angle of 45 degrees with respect to an upper surface of the semiconductor substrate, the first reflective mirror being formed on one end portion of the cavity, and
emitting a laser light from the upper surface side of the semiconductor substrate by reflecting the laser light on the first reflective mirror, the laser light proceeding along the direction parallel to the main surface, wherein
a second upper cladding layer formed of a semiconductor layer having a lower Al content than that of the upper cladding layer is formed on an upper portion of the upper cladding layer.

2. The semiconductor laser according to claim 1, wherein
the second upper cladding layer is formed of a semiconductor layer not containing Al.

3. The semiconductor laser according to claim 2, wherein
the upper cladding layer is made of AlGaAs or AlGaInP, and the second upper cladding layer is made of InGaP.

4. The semiconductor laser according to claim 1, wherein
an electric contact layer is formed on an upper portion of the second upper cladding layer, and
the second upper cladding layer is made of a semiconductor material having a band gap positioned between a band gap of the electric contact layer and a band gap of the upper cladding layer, or a semiconductor material relaxing an energy barrier for carriers between the electric contact layer and the upper cladding layer.

5. The semiconductor laser according to claim 1, wherein
a passivation film for preventing oxidization of the upper cladding layer exposed from the first reflective mirror is formed on a surface of the first reflective mirror.

6. The semiconductor laser according to claim 5, wherein
the passivation film is formed of an Al₂O₃ film or a dielectric film having an Al₂O₃ film as a main component.

7. The semiconductor laser according to claim 5, wherein
a first reflectance controlling film is formed on a plane of the second upper cladding layer in a region to which the laser light is emitted, and
the first reflectance controlling film and the passivation film are connected to each other.

8. The semiconductor laser according to claim 7, wherein
a second reflective mirror having an inclination of an acute angle of 45 degrees with respect to the upper surface of the semiconductor substrate on the other end portion of the cavity, and
a second reflectance controlling film having a higher reflectance to the laser light than that of the first reflectance controlling film is formed on a surface of the second upper cladding layer in a region where the second reflective mirror is formed.

9. The semiconductor laser according to claim 1, wherein
an impurity diffusion layer for suppressing re-absorption of the laser light is formed on the lower cladding layer, the active layer, and the upper cladding layer in vicinity of the first reflective mirror.

10. The semiconductor laser according to claim 1, wherein
a second reflective mirror having an inclination of an acute angle of 45 degrees with respect to an upper surface of the semiconductor substrate on the other end portion of the cavity, and
a reflective mirror reflecting the laser light is provided between the lower cladding layer and the semiconductor substrate.

11. The semiconductor laser according to claim 10, wherein
the reflective mirror is formed of a distributed Bragg reflector mirror configured by a multi-periodic structure of a high-refractive-index semiconductor layer and a low-refractive-index semiconductor layer.

12. A semiconductor laser of a horizontal-cavity horizontal-emitting type
having a cavity including a lower cladding layer, an active layer, and an upper cladding layer stacked on a main surface of a semiconductor substrate, the cavity being formed along a direction parallel to the main surface,
having at least the upper cladding layer formed of an Al-containing semiconductor layer among the lower cladding layer, the active layer, and the upper cladding layer,
having a first reflective mirror having an inclination of an acute angle of 45 degrees with respect to an upper surface of the semiconductor substrate, the first reflective mirror being formed on one end portion of the cavity, and
emitting a laser light from the other end portion of the cavity, the laser light proceeding along a parallel direction to the main surface, wherein
a second upper cladding layer formed of a semiconductor layer having a lower Al content than that of the upper cladding layer is formed on an upper portion of the upper cladding layer.

13. The semiconductor laser according to claim 12, wherein
a length of the cavity is 150 μm or shorter.
